(19) United States
(12) Patent Application Publication
(10) Pub. No.: US 2024/0174920 A1
(43) Pub. Date: May 30, 2024

(54) QUANTUM DOT, METHOD FOR PREPARING QUANTUM DOT, AND LIGHT EMITTING ELEMENT INCLUDING QUANTUM DOT

(71) Applicant: Samsung Display Co., Ltd., Yongin-si (KR)

(72) Inventors: JUNEHYUK JUNG, Yongin-si (KR); SUNGJAE KIM, Yongin-si (KR); Youngsik KIM, Yongin-si (KR); SEUNG-WON PARK, Yongin-si (KR); Bitna YOON, Yongin-si (KR); DONGHEE LEE, Yongin-si (KR)

(21) Appl. No.: 18/452,406

(22) Filed: Aug. 18, 2023

(30) Foreign Application Priority Data
Nov. 28, 2022 (KR) 10-2022-0161700

(51) Int. Cl. C09K 11/62; C09K 11/58; H10K 50/15

(52) U.S. Cl. CPC C09K 11/623; C09K 11/584; H10K 50/15

(57) ABSTRACT

A method for preparing a quantum dot includes supplying a first mixture including a first precursor material including a silver precursor, an indium precursor, a first gallium precursor, and a first solvent including oleylamine, trioctylphosphine oxide, and trioctylamine, adding a first sulfur precursor to the first mixture to form cores including silver, indium, gallium, and sulfur, reacting the cores with a second precursor material including a second sulfur precursor and a second gallium precursor to form a first shell around each of the cores, wherein the cores including the first shells comprise first particles, and adding a first element precursor and a second element precursor to a second mixture, the second mixture including the first particles and a second solvent, to form a second shell around each of the first shells.

### CROSS-REFERENCE TO RELATED APPLICATIONS

This application claims priority to and the benefit of Korean Patent Application No. 10-2022-0161700, filed on Nov. 28, 2022, the entire content of which is herein incorporated by reference.

### BACKGROUND

### 1. Field

Embodiments of the present disclosure relate to a display device and a method for manufacturing the same, and for example, to a display device having improved display efficiency and reliability, and a method for manufacturing the same.

### 2. Description of the Related Art

Various types (kinds) of display devices used for multimedia devices such as television sets, mobile phones, tablet computers, navigation systems, and game consoles are being developed. In such display devices, a so-called self-luminescent display element may be utilized, which accomplishes display by causing an organic compound-containing light emitting material to emit light.

In addition, the development of a light emitting element utilizing quantum dots as a light emitting material has been underway in an effort to enhance the color reproducibility (quality) of display devices, and there is a demand for an increase in lifespan and light emitting efficiency for light emitting elements utilizing quantum dots.

### SUMMARY

Aspects of one or more embodiments of the present disclosure are directed toward a quantum dot including a core containing silver, indium, gallium, and sulfur, and having a first shell, and a second shell, which thusly provides a quantum dot exhibiting high quantum yield and excellent or suitable chemical stability.

Aspects of one or more embodiments of the present disclosure are also directed toward a light emitting element having improved light emitting efficiency and color reproducibility.

Additional aspects will be set forth in part in the description which follows and, in part, will be apparent from the description, or may be learned by practice of the presented embodiments of the disclosure.

One or more embodiments of the present disclosure provides for a method for preparing a quantum dot, the method including
supplying a first mixture including a first precursor material including,
   a silver precursor, an indium precursor, and a first gallium precursor, and
   a first solvent containing oleylamine, trioctylphosphine oxide, and trioctylamine,
adding a first sulfur precursor to the first mixture to form cores, each of the cores including silver, indium, gallium, and sulfur,
reacting the cores with a second precursor material including a second sulfur precursor and a second gallium precursor to form a first shell around (e.g., surrounding) each of the cores, wherein the cores including the first shells include first particles, and
   adding a first element precursor and a second element precursor to a second mixture, the second mixture including the first particles and a second solvent to form a second shell around (e.g., surrounding) each of the first shells, wherein the first element precursor and the second element precursor each independently include at least one of a Group II element, a Group III element, a Group V element, a Group VI element, or a VII element.

In one or more embodiments, the first mixture may include the silver precursor in an amount of about 0.1 mmol to about 1 mmol, the indium precursor in an amount of about 0.1 mmol to about 0.5 mmol, the first gallium precursor in an amount of about 0.3 mmol to about 1 mmol, the trioctylphosphine oxide in an amount of about 0.1 mmol to about 1 mmol, the oleylamine in an amount of about 10 mmol to about 50 mmol, and the trioctylamine in an amount of about 1 mmol to about 20 mmol.

In one or more embodiments, the second precursor material may include the second sulfur precursor in an amount of about 1 mmol to about 2 mmol, and the second gallium precursor in an amount of about 1 mmol to about 5 mmol.

In one or more embodiments, the second mixture may include the first particles in an amount of about 0.1 mmol to about 100 mmol, and the second solvent in an amount of about 10 mmol to about 100 mmol.

In one or more embodiments, the second solvent may include at least one of oleylamine or trioctylamine.

In one or more embodiments, in the forming of the second shell, the first element precursor may be added in an amount of about 1 mmol to about 10 mmol, and the second element precursor may be added in an amount of about 1 mmol to about 10 mmol.

In one or more embodiments, the adding of the first sulfur precursor to the first mixture may be performed in a first temperature, and the first temperature may be about 300° C. or greater.

In one or more embodiments, the method may further include degassing the second mixture at a second temperature before the forming of the second shell.

In one or more embodiments, the second mixture may further include a third solvent, and a boiling point of the third solvent may be equal to or less than the second temperature.

In one or more embodiments of the present disclosure, a quantum dot includes a core including silver, indium, gallium, and sulfur, a first shell around (e.g., surrounding) the core and including GaS, and a second shell around (e.g., surrounding) the first shell and including a first element, wherein the first element includes at least one of a Group II element, a Group III element, a Group V element, a Group VI element, or a VII element.

In one or more embodiments, the second shell may include at least any one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

In one or more embodiments, the first shell may have a thickness of about 0.5 nm to about 3 nm, and the second shell may have a thickness of about 0.5 nm to about 4 nm.

In one or more embodiments, the second shell may be thicker than the first shell.

In one or more embodiments, the core may have a diameter of about 3 nm to about 7 nm.

In one or more embodiments, the core may include the silver in an amount of about 10 at % to about 20 at %, the indium in an amount of about 5 at % to about 30 at %, the gallium in an amount of about 0.2 at % to about 15 at %, and the sulfur in an amount of about 50 at % to about 60 at %.

In one or more embodiments, a ratio of the number of atoms of the gallium in the entire quantum dot to the number of atoms of the indium in the entire quantum dot may be about 0.01 to about 2, and a ratio of the number of atoms of the first element in the entire quantum dot to the number of atoms of the indium in the entire quantum dot may be about 0.5 to about 1.

In one or more embodiments, the quantum dot may have a central emission wavelength of about 510 nm to about 540 nm.

In one or more embodiments, quantum yield retention represented by Equation 1 may be about 90% or greater:

Quantum yield retention=X₁/X₀ Equation 1

In Equation 1, X₁ is a quantum yield of the quantum dot as measured after three times of purification with ethanol, and X₀ is a quantum yield of the quantum dot before the purification.

In one or more embodiments of the present disclosure, a light emitting element includes a first electrode, a hole transport region on the first electrode, an emission layer on the hole transport region and including quantum dots, an electron transport region on the emission layer, and a second electrode on the electron transport region, wherein each of the quantum dots include a core including silver, indium, gallium, and sulfur, a first shell around (e.g., surrounding) the core and including GaS, and a second shell around (e.g., surrounding) the first shell and including a first element, and wherein the first element includes at least one of a Group II element, a Group III element, a Group V element, a Group VI element, or a Group VII element.

In one or more embodiments, the second shell may include at least any one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a combined perspective view of an electronic device according to one or more embodiments of the present disclosure;

FIG. 2 is an exploded perspective view of an electronic device according to one or more embodiments of the present disclosure;

FIG. 3 is a cross-sectional view of a display device taken along line I-I′ of FIG. 1, according to one or more embodiments of the present disclosure;

FIG. 4 is a cross-sectional view of a light emitting element according to one or more embodiments of the present disclosure;

FIG. 5 is a schematic view showing a structure of a quantum dot according to one or more embodiments of the present disclosure;

FIG. 6 is an enlarged plan view showing a portion of a display device according to one or more embodiments of the present disclosure;

FIG. 7 is a cross-sectional view of a display device taken along line II-II′ of FIG. 6, according to one or more embodiments of the present disclosure;

FIG. 8 is a cross-sectional view of a display device according to one or more embodiments of the present disclosure;

FIG. 9 is a flowchart showing a method for preparing a quantum dot according to one or more embodiments of the present disclosure;

FIG. 10A is a line graph showing a photoluminescence spectrum of a quantum dot of Example 1;

FIG. 10B is a line graph showing a photoluminescence spectrum of a quantum dot of Example 2; and

FIG. 11 is a line graph showing the absorption and emission spectra of Examples and Comparative Examples.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure. The embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

Like numbers refer to like elements throughout, and duplicative descriptions thereof may not be provided. In addition, in the drawings, the thickness, the ratio, and the dimensions of elements may be exaggerated for an effective description of technical contents. The term “and/or,” includes any and all combinations of one or more of the associated listed items. Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It should be understood that the terms “comprise,” “include”, or “have,” when used in this specification, are intended to specify the presence of stated features, integers, steps, operations, elements, components, or combinations thereof in the disclosure, but do not preclude the presence or addition of one or more other features, integers, steps, operations, elements, components, or combinations thereof.

As used herein, being “disposed directly on” may mean that there is no additional layer, film, region, plate, and/or the like between a part and another part such as a layer, a film, a region, a plate, and/or the like. For example, being “disposed directly on” may mean that two layers or two members are disposed without using an additional member such as an adhesive member, therebetween.

As used herein, the term “Group” refers to a group the IUPAC periodic table of elements.

As used herein, “Group II” may include Group IIA elements and Group IIB elements. For example, the Group II elements may be magnesium (Mg) or zinc (Zn), but the present disclosure is not limited thereto.

As used herein, “Group III” may include Group IIIA elements and Group IIIB elements. For example, the Group III elements may be aluminum (Al), indium (In), gallium (Ga), or titanium (Ti), but the present disclosure is not limited thereto.

As used herein, “Group V” may include Group VA elements and Group VB elements. For example, the Group V elements may be phosphorus (P), arsenic (As), or antimony (Sb), but the present disclosure is not limited thereto.

As used herein, “Group VI” may include Group VIA elements and Group VIB elements. For example, the Group VI elements may be oxygen (O), sulfur (S), selenium (Se) or tellurium (Te), but the present disclosure is not limited thereto.

As used herein, “Group VII” may include Group VIIA elements. For example, the Group VII elements may be manganese (Mn), but the present disclosure is not limited thereto.

In the present disclosure, when particles are spherical, “diameter” indicates a particle diameter or an average particle diameter, and when the particles are non-spherical, the “diameter” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a quantum dot, a light emitting element, and a display device including the same according to one or more embodiments of the present disclosure will be described with reference to the accompanying drawings.

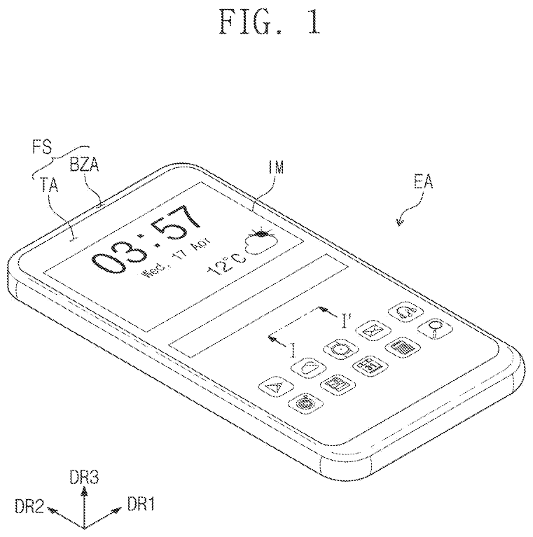

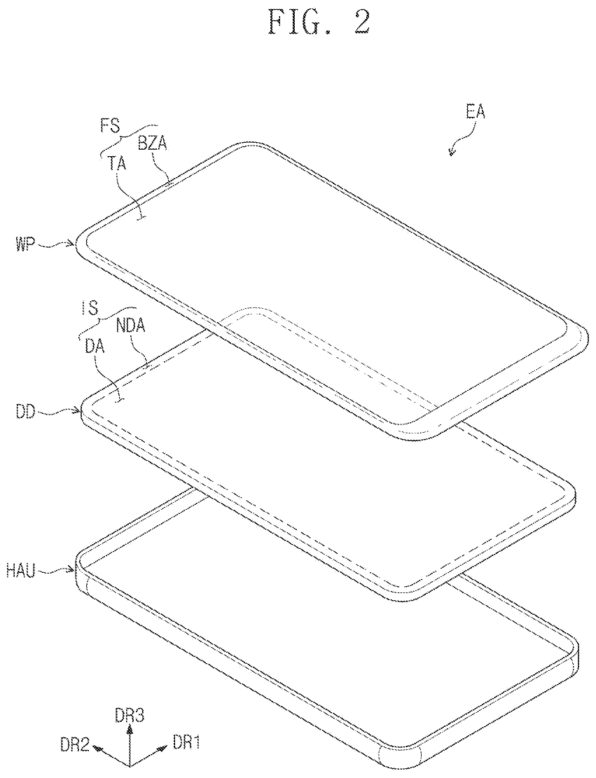

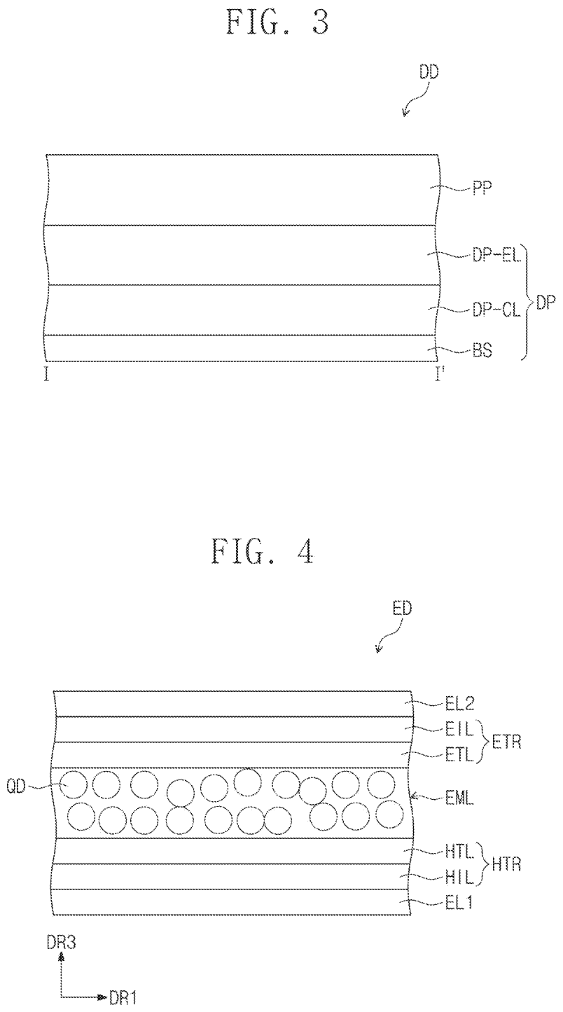

FIG. 1 is a perspective view showing an electronic device EA according to one or more embodiments of the present disclosure. FIG. 2 is an exploded perspective view of the electronic device EA according to one or more embodiments of the present disclosure. FIG. 3 is a cross-sectional view of a display device DD taken along line I-I′ of FIG. 1, according to one or more embodiments of the present disclosure. FIG. 4 is a cross-sectional view of a light emitting element ED of one or more embodiments of the present disclosure.

In one or more embodiments, an electronic device EA may be a large-sized electronic device such as a television set, a monitor, or an outdoor billboard. In one or more embodiments, the electronic device EA may be a small- or medium-sized electronic device such as a personal computer, a laptop computer, a personal digital terminal, a car navigation unit, a game console, a smartphone, a tablet, or a camera. These devices are merely provided as embodiments, and other electronic devices may be employed without departing from the scope of the present disclosure. In the present embodiment, as an example, a smartphone is shown as the electronic device EA.

The electronic device EA may include a display device DD and a housing HAU. The display device DD may display an image IM through a display surface IS, and a user may view images provided through a transmission region TA corresponding to a front surface FS of the electronic device EA. The image IM may include still images as well as dynamic images. FIG. 1 shows that the front surface FS is parallel to a plane defined by a first direction DR1 and a second direction DR2 crossing the first direction DR1. However, this is merely an example, and the front surface FS of the electronic device EA in one or more embodiments may have a curved shape.

Among the normal directions of the front surface FS of the electronic device EA, that is, the thickness directions of the electronic device EA, a direction in which the image IM is displayed is indicated by a third direction DR3. A front surface (or an upper surface) and a rear surface (or a lower surface) of respective members may be defined by the third direction DR3.

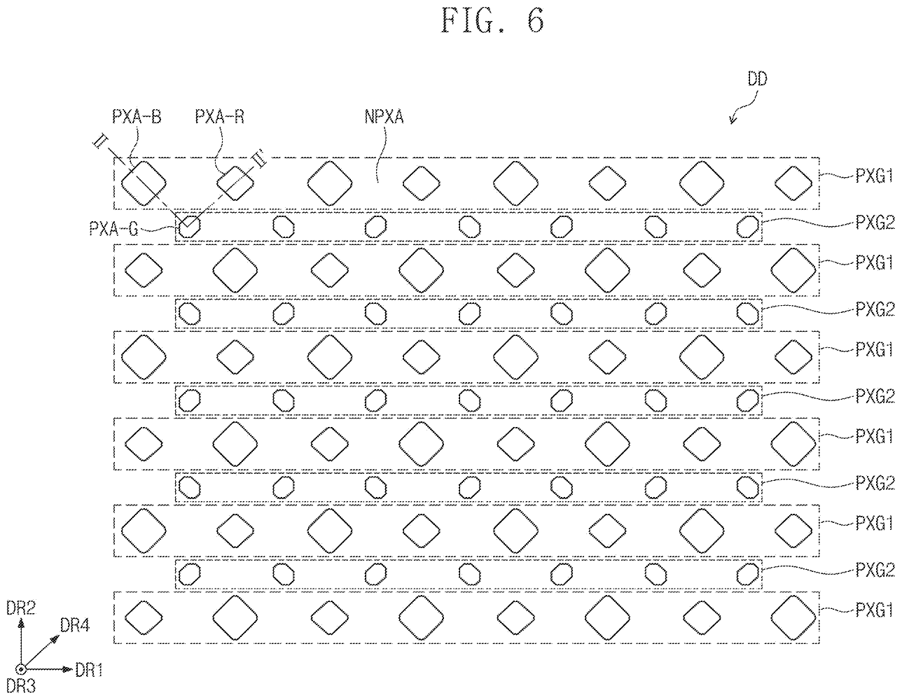

A fourth direction DR4 (see, e.g., FIG. 6) may be a direction between the first direction DR1 and the second direction DR2. The fourth direction DR4 may be positioned on a plane parallel to the plane defined by the first direction DR1 and the second direction DR2. In one or more embodiments, the directions indicated by the first to fourth directions DR1, DR2, DR3, and DR4 are relative concepts, and may thus be changed to other directions.

In one or more embodiments, the electronic device EA may include a foldable display device having a folding region and a non-folding region, or a bending display device having at least one bending portion.

The electronic device EA may include a display device DD and a housing HAU. The front surface FS in the electronic device EA may correspond to a front surface of the display device DD and may correspond to a front surface of a window WP. Accordingly, like reference numerals will be given for the front surface of the electronic device EA, the front surface of the display device DD, and the front surface of the window WP.

The housing HAU may accommodate the display device DD. The housing HAU may be disposed to cover the display device DD while exposing the display surface IS, that is a top surface of the display device DD. The housing HAU may cover side surfaces and a bottom surface of the display device DD, and may expose the entire top surface. However, the present disclosure is not limited thereto, and the housing HAU may cover a portion of the top surface as well as the side surfaces and the bottom surface of the display device DD.

In the electronic device EA of one or more embodiments, the window WP may include an optically transparent insulating material. The window WP may include a transmission region TA and a bezel region BZA. A front surface FS of the window WP including the transmission region TA and the bezel region BZA corresponds to a front surface FS of the electronic device EA.

In FIGS. 1 and 2, the transmission region TA is shown to have a rectangular shape with rounded corners. However, this is presented as an example, and the transmission region TA may have one or more suitable shapes and is not limited to any one embodiment.

The transmission region TA may be an optically transparent region. The bezel region BZA may be a region having a relatively lower light transmittance than the transmission region TA. The bezel region BZA may have a set or predetermined color. The bezel region BZA may be adjacent to the transmission region TA and surround the transmission region TA. The bezel region BZA may define the shape of the transmission region TA. However, the present disclosure is not limited thereto, and the bezel region BA may be disposed adjacent to only one side of the transmission region TA, and a portion thereof may not be provided.

The display device DD may be disposed below the window WP. As utilized herein, “below” may indicate a direction opposite to the direction in which the display device DD provides an image.

In one or more embodiments, the display device DD may be substantially configured to generate an image IM. The image IM generated in the display device DD is displayed on the display surface IS, and is viewed by users through the transmission region TA from the outside. The display device DD includes a display region DA and a non-display region NDA. The display region DA may be a region activated according to electrical signals. The non-display region NDA may be a region covered by the bezel region BZA. The non-display region NDA is adjacent to the display region DA. The non-display region NDA may be around (e.g., may surround) the display region DA.

Referring to FIG. 3, the display device DD may include a display panel DP and a light control layer PP disposed on the display panel DP. The display panel DP may include a display element layer DP-EL. The display element layer DP-EL includes a light emitting element ED.

The light control layer PP may be disposed on the display panel DP to control reflected light in the display panel DP due to external light. The light control layer PP may include, for example, a polarizing layer or a color filter layer.

In the display device DD according to one or more embodiments, the display panel DP may be a light emitting display panel. For example, the display panel DP may be a quantum dot light emitting display panel including a quantum dot light emitting element. However, the present disclosure is not limited thereto.

The display panel DP may include a base substrate BS, a circuit layer DP-CL disposed on the base substrate BS, and a display element layer DP-EL disposed on the circuit layer DP-CL.

The base substrate BS may be a member providing a base surface in which the display element layer DP-EL is disposed. The base substrate BS may be a glass substrate, a metal substrate, a plastic substrate, etc. However, the present disclosure is not limited thereto, and the base substrate BS may be an inorganic layer, an organic layer, or a composite material layer. The base substrate BS may be a flexible substrate that may be readily bent or folded.

In one or more embodiments, the circuit layer DP-CL may be disposed on the base substrate BS, and the circuit layer DP-CL may include a plurality of transistors. The transistors may each include a control electrode, an input electrode, and an output electrode. For example, the circuit layer DP-CL may include a switching transistor and a driving transistor for driving the light emitting element ED of the display element layer DP-EL.

FIG. 4 is a view showing a light emitting element ED according to one or more embodiments, and referring to FIG. 4, the light emitting element according to one or more embodiments includes a first electrode EL1, a second electrode EL2 facing the first electrode EL1, and a plurality of functional layers disposed between the first electrode EL1 and the second electrode EL2 and having an emission layer EML.

The plurality of functional layers may include a hole transport region HTR disposed between the first electrode EL1 and the emission layer EML, and an electron transport region ETR disposed between the second electrode EL2 and the emission layer EML. In one or more embodiments, a capping layer may be further disposed on the second electrode EL2.

The hole transport region HTR and the electron transport region ETR each may include a plurality of sub functional layers. For example, the hole transport region HTR may include a hole injection layer HIL and a hole transport layer HTL as a sub functional layer, and the electron transport region ETR may include an electron injection layer EIL and an electron transport layer ETL as a sub functional layer. However, the present disclosure is not limited thereto, and the hole transport region HTR may further include an electron blocking layer as a sub functional layer, and the electron transport region ETR may further include a hole blocking layer as a sub functional layer.

In the light emitting element ED according to one or more embodiments, the first electrode EL1 has conductivity (e.g., is a conductor). The first electrode EL1 may be formed of a metal alloy or a conductive compound. The first electrode EL1 may be an anode. The first electrode EL1 may be a pixel electrode.

In the light emitting element ED according to one or more embodiments, the first electrode EL1 may be a reflective electrode. However, the present disclosure is not limited thereto. For example, the first electrode EL1 may be a transmissive electrode or a transflective electrode. When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (e.g., a mixture of Ag and Mg). In one or more embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may be a multilayer metal film and may have a structure in which metal films of ITO/Ag/ITO are stacked.

The hole transport region HTR is provided on the first electrode EL1. The hole transport region HTR may include a hole injection layer HIL, a hole transport layer HTL, etc. In one or more embodiments, the hole transport region HTR may further include at least one of a hole buffer layer or an electron blocking layer in addition to the hole injection layer HIL and the hole transport layer HTL. The hole buffer layer may compensate for a resonance distance according to the wavelength of light emitted from an emission layer EML, and may thus increase luminous efficiency. Materials which may be included in the hole transport region HTR may be utilized as materials included in the hole buffer layer. The electron blocking layer is a layer that serves to prevent or reduce electrons from being injected into the hole transport region HTR from the electron transport region ETR.

The hole transport region HTR may have a single layer formed of a single material, a single layer formed of a plurality of different materials, or a multilayer structure having a plurality of layers formed of a plurality of different materials. For example, the hole transport region HTR may have a single-layer structure formed of a plurality of different materials, or a structure in which a hole injection layer HIL/hole transport layer HTL, a hole injection layer HIL/hole transport layer HTL/hole buffer layer, a hole injection layer HIL/hole buffer layer, a hole transport layer HTL/hole buffer layer, or a hole injection layer HIL/hole transport layer HTL/electron blocking layer are stacked in order from the first electrode EL1, but the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole injection layer HIL may include, for example, a phthalocyanine compound such as copper phthalocyanine, N, N′-diphenyl-N, N′-bis-[4-(phenyl-m-tolyl-amino)-phenyl]-biphenyl-4,4′-diamine (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-I-yl)-N,N′-diphenyl-benzidine (NPD), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), and/or the like.

The hole transport layer HTL may include a material generally available in the art. For example, the hole transport layer HTL may further include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4,4″-tris(N-carbazolyl)triphenylamine (TCTA), N,N′-di(naphthalene-I-yl)-N,N′-diphenyl-benzidine (NPD), 4,4-cyclohexylidene bis[N, N-bis(4-methylphenyl]benzenamine] (TAPC), 4,4-bis[N,N′-(3-tolyl)amino]-3,3′-dimethylbiphenyl (HMTPD), 1,3-bis(N-carbazolyl)benzene (mCP), and/or the like.

The hole transport region HTR may have a thickness of about 5 nm to about 1,500 nm, for example, about 10 nm to about 500 nm. The hole injection layer HIL, for example, may have a thickness of about 3 nm to about 100 nm, and the hole transport layer HTL may have a thickness of about 3 nm to about 100 nm. For example, an electron blocking layer may have a thickness of about 1 nm to about 100 nm. When the thicknesses of the hole transport region HTR, the hole injection layer HIL, the hole transport layer HTL, and the electron blocking layer satisfy the above-described ranges, satisfactory hole transport properties may be obtained without a substantial increase in driving voltage.

The emission layer EML is provided on the hole transport region HTR. The emission layer EML includes a plurality of quantum dots QD.

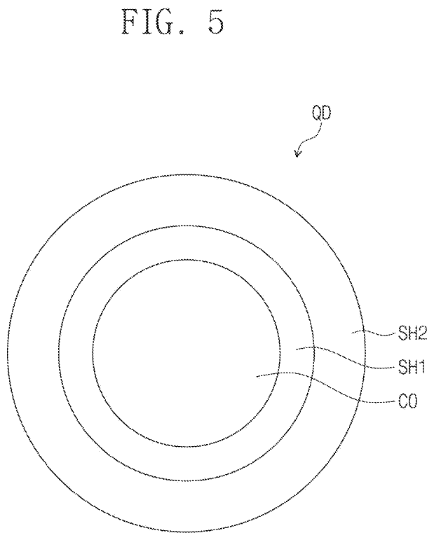

The quantum dots QD included in the emission layer EML may be stacked to form a layer. In FIG. 4, as an example, the quantum dots QD having a circular cross-section are arranged to form two layers, but the present disclosure is not limited thereto. For example, depending on the thickness of the emission layer EML, the shape of the quantum dots QD included in the emission layer EML, the average diameter of the quantum dots QD, and/or the like, the arrangement of the quantum dots QD may vary. To be specific, in the emission layer EML, the quantum dots QD are arranged adjacent to each other to form a single layer, or a plurality of layers such as two or three layers. The quantum dots QD according to one or more embodiments will be described in more detail with reference to FIGS. 5 to 7.

In the light emitting element ED according to one or more embodiments, the emission layer EML may include a host and a dopant. In one or more embodiments, the emission layer EML may include the quantum dots QD as a dopant material. In one or more embodiments, the emission layer EML may further include a host material.

In the light emitting element ED according to one or more embodiments, the emission layer EML may be to emit fluorescence. For example, the quantum dots QD may be utilized as a fluorescent dopant material.

In the light emitting element ED of one or more embodiments, the electron transport region ETR is provided on the emission layer EML. The electron transport region ETR may include at least one among a hole blocking layer, an electron transport layer ETL, and an electron injection layer EIL, but the present disclosure is not limited thereto.

The electron transport region ETR may have a single layer formed of a single material, a single layer formed of a plurality of different materials, or a multilayer structure having a plurality of layers formed of a plurality of different materials.

For example, the electron transport region ETR may have a single layer structure of an electron injection layer EIL or an electron transport layer ETL, and may have a single layer structure formed of an electron injection material and an electron transport material. In one or more embodiments, the electron transport region ETR may have a single layer structure formed of a plurality of different materials, or may have a structure in which an electron transport layer ETL/electron injection layer EIL, or a hole blocking layer/electron transport layer ETL/electron injection layer EIL are stacked in order from the emission layer EML, but the present disclosure is not limited thereto. The electron transport region ETR may have a thickness of, for example, about 20 nm to about 150 nm.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

When the electron transport region ETR includes the electron transport layer ETL, the electron transport region ETR may include an anthracene-based compound. However, the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), or a mixture thereof. The electron transport layers ETL may have a thickness of about 10 nm to about 100 nm, for example, about 15 nm to about 50 nm. When the thickness of the electron transport layers ETL satisfies the above-described ranges, satisfactory electron transport properties may be obtained without a substantial increase in driving voltage.

When the electron transport region ETR includes the electron injection layer EIL, the electron transport region ETR may include a halogenated metal such as LiF, NaCl, CsF, RbCl, and RbI, a lanthanide metal such as Yb, a metal oxide such as Li₂O and BaO, or lithium quinolate (LiQ), and/or the like, but the present disclosure is not limited thereto. The electron injection layers EIL may also be formed of a mixture material of an electron transport material and an insulating organometallic salt. For example, the organometallic salt may include, for example, metal acetates, metal benzoates, metal acetoacetates, metal acetylacetonates, or metal stearates. The electron injection layer EIL may have a thickness of about 0.1 nm to about 10 nm, for example, about 0.3 nm to about 9 nm. When the thickness of the electron injection layers EIL satisfies the above-described ranges, satisfactory electron injection properties may be obtained without a substantial increase in driving voltage.

As described above, the electron transport region ETR may include a hole blocking layer. The hole blocking layer may include, for example, at least one of 2,9-dimethyl-4,7-diphenyl-1,10-phenanthroline (BCP) or 4,7-diphenyl-1,10-phenanthroline (Bphen), but the present disclosure is not limited thereto.

The second electrode EL2 is provided on the electron transport region ETR. The second electrode EL2 may be a common electrode or a cathode. The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, or a compound containing any of the aforementioned elements (e.g., AgYb, a compound of AgMg and MgAg, and/or the like depending on the amount) or a mixture containing any of the aforementioned elements (e.g., a mixture of Ag and Mg). In one or more embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like.

The second electrode EL2 may be connected with an auxiliary electrode. When the second electrode EL2 is connected with the auxiliary electrode, the resistance of the second electrode EL2 may decrease.

FIG. 5 is a view schematically showing a structure of a quantum dot according to one or more embodiments of the present disclosure.

Referring to FIG. 5, the quantum dots QD may include a core CO, a first shell SH1 around (e.g., surrounding) the core CO, and a second shell SH2 around (e.g., surrounding) the first shell SH1.

The core CO may include Group I-III-VI semiconductor compounds. The core CO may be a semiconductor compound having a chalcopyrite structure. The core CO may be a Group I-III-VI quaternary AgInGaS compound. The core CO may include silver (Ag), indium (In), gallium (Ga), and sulfur (S). The core CO may be formed of silver, indium, gallium, and sulfur. The quantum dots QD of one or more embodiments include the core CO containing Group I-III-VI semiconductor compounds, and may thus have a high blue light absorption rate.

In one or more embodiments, the quantum dots QD may be non-Cd-based quantum dots. For example, the quantum dots QD may not include (e.g., may exclude) cadmium (Cd).

The core may include silver in an amount of about 10 at % to about 20 at %, indium in an amount of about 5 at % to about 30 at %, gallium in an amount of about 0.2 at % to about 15 at %, and sulfur in an amount of about 50 at % to about 60 at %. When the amounts of silver, indium, gallium, and sulfur included in the core CO are regulated within the ranges described above, the quantum dots QD of one or more embodiments may have high quantum efficiency and optical stability. The quantum dots QD include the amounts of elements included in the core CO within the ranges described above, and may thus emit light having a desired or suitable emission wavelength. With changes in the amounts of silver, indium, gallium, and sulfur included in the core CO within the ranges described above, regulating the quantum dots QD to have a desired or suitable emission wavelength may be achieved. For example, when the amount of elements included in the core CO satisfies the ranges described above, the quantum dots QD may be to emit light having an emission wavelength of about 510 nm to about 540 nm. Accordingly, the quantum dots QD may be to emit green light having high color purity.

The core CO including silver, indium, gallium, and sulfur may have an absorption wavelength of about 350 nm to about 530 nm. Accordingly, the core CO may be to absorb blue light in the wavelength ranges described above to emit green light or red light. The emission wavelength of light emitted from the quantum dots QD may be controlled or selected by regulating the size of the core CO, the thickness of the first shell SH1 and the second shell SH2, and/or the like.

The first shell SH1 may include Group III-VI semiconductor compounds. The first shell SH1 may include GaS. The first shell SH1 may be formed of GaS.

The second shell SH2 may include a first element. In one or more embodiments, the first element may include at least one of a Group II element, a Group III element, a Group V element, a Group VI element, or a VII element. The first element included in the second shell SH2 may include at least one of a Group IIA element, a Group IIB element, a Group IIIB element, a Group VB element, a Group VIB element, or a Group VIIA element.

In one or more embodiments, the second shell SH2 may further include a second element. For example, the second shell SH2 may include the first element and the second element. The second element may include at least one of a Group II element, a Group III element, a Group V element, a Group VI element, or a VII element. The second element included in the second shell SH2 may include at least one of a Group IIA element, a Group IIB element, a Group IIIB element, a Group VB element, a Group VIB element, or a Group VIIA element.

In one or more embodiments, when the second shell SH2 includes the first element and the second element, the first element may be a Group II element, a Group Ill element, or a VII element, and the second element may be a Group II element, a Group V element, or a Group VI element. For example, the first element may be a Group IIB element, a Group IIIB element, or a Group VIIA element, and the second element may be a Group IIA element, a Group VB element, or a Group VIB element. In one or more embodiments, the first element may be a Group III element, and the second element may be a Group V element. For example, the first element may be a Group IIIB element and the second element may be a Group VIB element.

The second shell may include at least any one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe. In one or more embodiments, the second shell SH2 may be formed of ZnS.

The second shell SH2 may completely cover the first shell SH1. Accordingly, the surface of the quantum dots QD may be defined by an outer surface of the second shell SH2. Covered by the second shell SH2, the first shell SH1 may not be exposed in the quantum dots QD.

The quantum dots QD of one or more embodiments include the second shell SH2 around (e.g., surrounding) the first shell SH1 to have a narrow full width of half maximum (FWHM), and may thus have both (e.g., simultaneously) improved quantum yield and quantum yield retention. The first shell SH1 including GaS has an amorphous shape, and accordingly, chemical stability may be reduced. Accordingly, in quantum dots including only the core CO and the first shell SH1, the quantum yield may be reduced due to the denaturation of the first shell SH in the process of purification. According to one or more embodiments of the present disclosure, the quantum dots QD of include the second shell SH2 around (e.g., surrounding) the first shell SH1, and may thus exhibit excellent or suitable chemical stability leading to improved quantum yield.

A ratio of the number of atoms of the element gallium to the element indium included in the quantum dots QD may be about 0.01 to about 2. For example, when the core CO includes AgInGaS, the first shell SH1 includes GaS, and the second shell SH2 includes ZnS, an amount of gallium included in the entire quantum dots QD with respect to a total amount of indium included in the core CO may be about 1 at % (atomic percent) to about 200 at %. For example, the ratio of the number of atoms of the element gallium to the element indium included in the quantum dots QD may be represented by Equation A.

(G₁+G₂+G₃)/In Equation A

In Equation A above, G₁ indicates the number (of atoms) of the element gallium included in the core CO, G₂ indicates the number (of atoms) of the element gallium included in the first shell SH1, and G₃ indicates the number (of atoms) of the element gallium included in the second shell SH2. In Equation A above, when the second shell SH2 does not include a Group III element, G₃ may be 0.

A ratio of the number of atoms of the first element to the element indium included in the quantum dots QD may be about 0.5 to about 1. For example, a ratio of the number of atoms of the first element to the element indium included in the quantum dots QD may be about 0.6 to about 0.9. For example, when the core CO includes AgInGaS, the first shell SH1 includes GaS, and the second shell SH2 includes ZnS, an amount of zinc in the second shell SH2 with respect to a total amount of indium included in the core CO may be about 50 at % to about 100 at %. In one or more embodiments, the amount of elements included in the quantum dots QD may be measured through inductively coupled plasma atomic emission spectroscopy (ICP-AES), but the present disclosure is not limited thereto.

A thickness of the second shell SH2 included in the quantum dots QD may vary depending on an atomic ratio of an element included in the second shell SH2 to a Group III element among elements included in the core CO. When the amount of the first element in the second shell SH2 relative to the element indium of the core CO satisfies the ranges described above, the thickness of the second shell SH2 is regulated to a desired or suitable range, thereby providing quantum dots QD having high sphericity and a high absorption rate.

The second shell SH2 may have a single layer or multilayer structure. For example, the second shell SH2 may have a single layer formed of a single material, a single layer formed of a plurality of different materials, or a multilayer structure having a plurality of layers formed of a plurality of different materials. When the second shell SH2 has a multilayer structure, the composition of each layer may be different. In this case, the composition of each layer may discontinuously change within the second shell SH2 or may continuously change within the second shell SH2.

As the quantum dots QD of one or more embodiments include the first shell SH1 and the second shell SH2, a passivation effect for the core CO may be excellent or suitable. Accordingly, the quantum dots QD of one or more embodiments may exhibit high quantum yield properties.

In one or more embodiments, the quantum dots QD may have a thickness of about 5 nm to about 15 nm. When the quantum dots QD satisfy the average particle diameter ranges described above, a characteristic behavior as quantum dots QD and excellent or suitable dispersibility as well may be achieved. In one or more embodiments, when the average particle diameter of the quantum dots QD is variously selected within the ranges as described above, the emission wavelength of the quantum dots QD and/or the semiconductor properties of the quantum dots may be variously changed.

In one or more embodiments, the form of the quantum dots QD is not particularly limited as long as it is a form commonly utilized in the art, but more specifically, quantum dots in the form of spherical, pyramidal, multi-arm, or cubic nanoparticles, nanotubes, nanowires, nanofibers, nanoplatelets, and/or the like may be utilized. In one or more embodiments, the quantum dots QD may be spherical or substantially spherical.

The quantum dots QD may be to emit green light. The quantum dots QD may have a central emission wavelength of about 510 nm to about 540 nm. For example, quantum dots QD may be to emit light having a maximum emission wavelength of about 510 nm to about 540 nm. However, the present disclosure is not limited thereto, and the quantum dots QD may be to emit red light. For example, the quantum dots QD may have a central emission wavelength of about 630 nm to about 680 nm. For example, the quantum dots QD may be to emit light having a maximum emission wavelength of about 630 nm to about 680 nm.

In one or more embodiments, the quantum dots QD may have a full width of half maximum (FWHM) of an emission wavelength spectrum of about 50 nm or less. For example, the quantum dots QD may have a full width of half maximum of an emission wavelength spectrum of about 40 nm or less. When the full width of half maximum of the quantum dots QD satisfies the ranges described above, color purity and color reproducibility of the quantum dots QD may be improved. In one or more embodiments, light emitted through the quantum dots QD is emitted in all directions, and thus a wide viewing angle may be improved.

The quantum dots QD may further include a ligand chemically bonded to a surface. The ligand may be chemically bonded to the surface of the quantum dots QD to passivate the quantum dots QD. For example, the quantum dots QD may further include a ligand chemically bonded to the second shell SH2. In one or more embodiments, the ligand may include an organic ligand or a metal halide.

In one or more embodiments, the quantum dots QD may have a quantum efficiency retention represented by Equation 1 of 90% or greater. As the quantum dots QD have a quantum efficiency retention of 90% or greater, the quantum dots QD may exhibit excellent or suitable chemical stability, and thus, denaturation in the process of purification process or due to an external environment may be prevented or reduced.

Quantum yield retention=X₁/X₀ Equation 1

In Equation 1 above, X₁ is the quantum yield of a quantum dot as measured after three times of purification with ethanol, and X₀ is the quantum yield of a quantum dot before the purification.

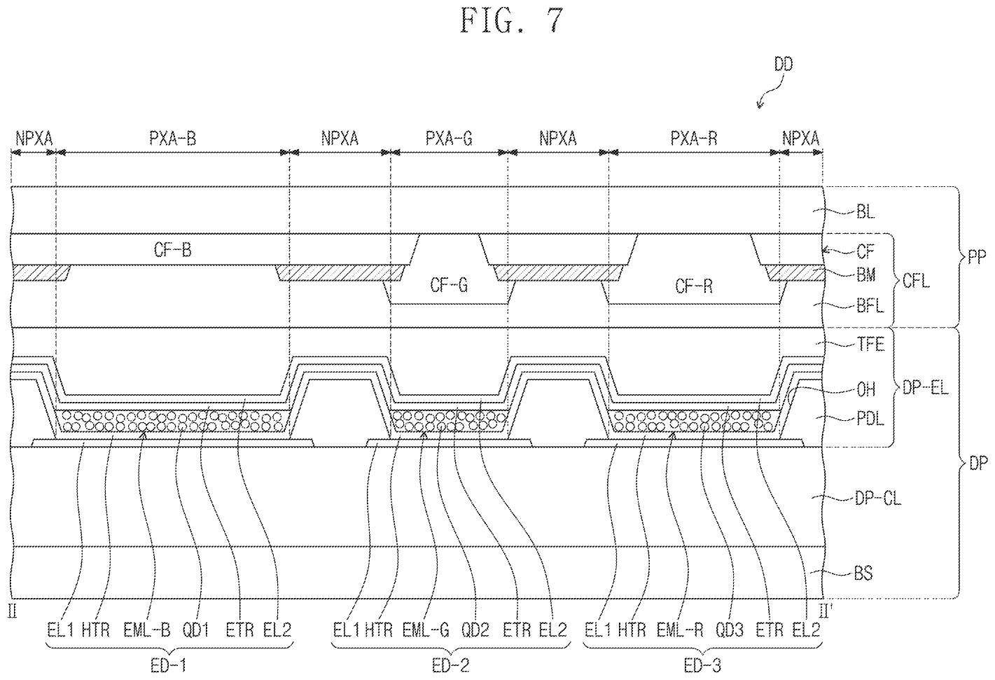

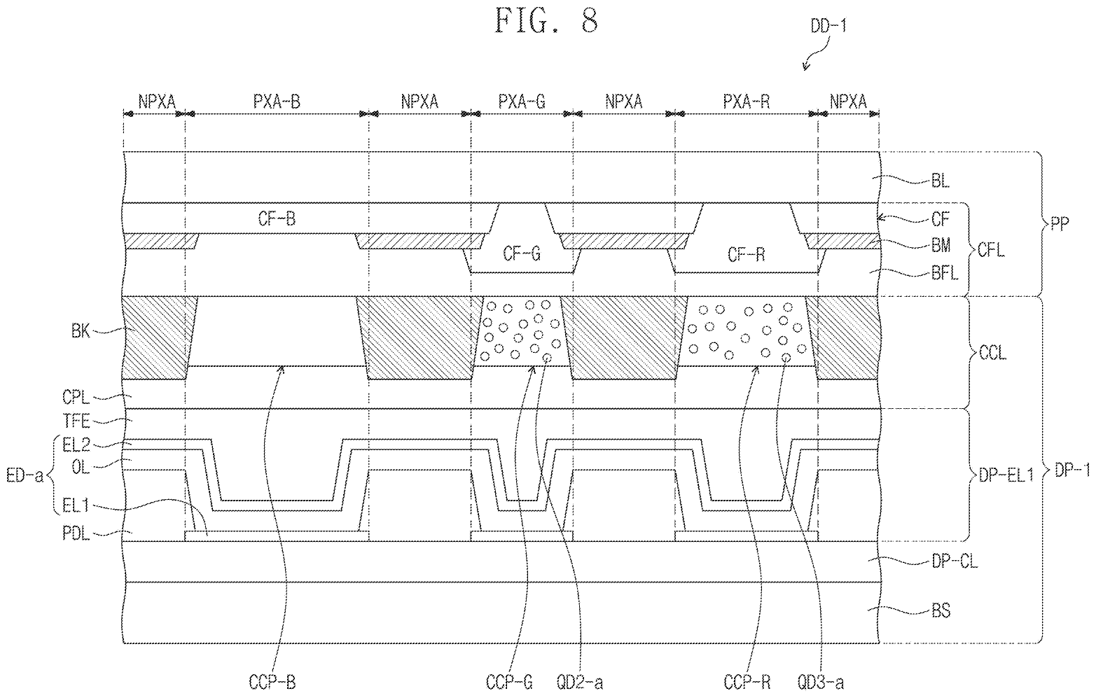

FIG. 6 is an enlarged plan view showing a portion of a display device DD according to one or more embodiments of the present disclosure. FIG. 7 is a cross-sectional view of a display device DD according to one or more embodiments of the present disclosure. FIG. 7 shows a portion taken along line II-II′ of FIG. 6, according to one or more embodiments of the present disclosure. FIG. 8 is an enlarged plan view showing a portion of a display device according to one or more embodiments of the present disclosure. FIG. 8 is a cross-sectional view of a display device DD-1 according to one or more embodiments of the present disclosure. FIG. 8 shows a portion of a display region DA of a display panel taken along line II-II′ of FIG. 6, according to one or more embodiments of the present disclosure.

Referring to FIGS. 6 to 8, the display device DD may include a non-light emitting region NPXA and light emitting regions PXA-B, PXA-G, and PXA-R. The light emitting regions PXA-B, PXA-G, and PXA-R each may be a region emitting light generated from each of light emitting elements ED-1, ED-2, and ED-3. The light emitting regions PXA-B, PXA-G, and PXA-R may be spaced apart from one another when viewed on a plane (e.g., in a plan view).

The light emitting regions PXA-B, PXA-G, and PXA-R may be divided into a plurality of groups according to color of light generated from the light emitting elements ED-1, ED-2, and ED-3. In the display device DD of one or more embodiments shown in FIGS. 6 to 8, three light emitting regions PXA-B, PXA-G, and PXA-R which emit blue light, green light, and red light, are shown as an example. For example, the display devices DD and DD-1 of one or more embodiments may include a blue light emitting region PXA-B, a green light emitting region PXA-G, and a red light emitting region PXA-R, which are distinct from one another.

Referring to FIG. 6, the blue light emitting regions PXA-B and the red light emitting regions PXA-R may be alternately arranged with one another in the first direction DR1 to form a first group PXG1. The green light emitting regions PXA-G may be arranged with one another in the first direction DR1 to form a second group PXG2. The first group PXG1 and the second group PXG2 may be spaced apart from one another in the second direction DR2. Each of the first group PXG1 and the second group PXG2 may be provided in plural. The first groups PXG1 and the second groups PXG2 may be alternately arranged in the second direction DR2. One green light emitting region PXA-G may be disposed spaced apart (spaced) from one blue light emitting region PXA-B or one red light emitting region PXA-R in the fourth direction DR4. The fourth direction DR4 may be a direction between the first direction DR1 and the second direction DR2. The arrangement structure of the light emitting regions PXA-B, PXA-G, and PXA-R shown in FIG. 6 may be referred to as a PENTILE®^{T} structure. PENTILE® is a registered trademark of Samsung Display, Co., Ltd., Republic of Korea.

However, the present disclosure is not limited thereto, and the light emitting regions PXA-R, PXA-B, and PXA-G may have one or more suitable types (kinds) of polygons or circles, and an arrangement structure of the light emitting regions is also not limited. For example, in one or more embodiments, the light emitting regions PXA-B, PXA-G, and PXA-R may have a stripe structure in which the blue light emitting region PXA-B, the green light emitting region PXA-G, and the red light emitting region PXA-R may be alternately arranged along the first direction DR1, or may be arranged in the form of a diamond (DIAMOND PIXEL®). DIAMOND PIXEL® is a registered trademark of Samsung Display, Co., Ltd., Republic of Korea.

Referring to FIG. 7, the plurality of light emitting elements ED-1, ED-2, and ED-3 may be to emit light having different wavelength ranges. For example, in one or more embodiments, the display device DD may include a first light emitting element ED-1 emitting blue light, a second light emitting element ED-2 emitting green light, and a third light emitting element ED-3 emitting red light. However, the present disclosure is not limited thereto, and the first to third light emitting elements ED-1, ED-2 and ED-3 may be to emit light in substantially the same wavelength range or emit light in at least one different wavelength range.

For example, the blue light emitting region PXA-B, the green light emitting region PXA-G, and the red light emitting region PXA-R of the display device DD may correspond to the first light emitting element ED-1, the second light emitting element ED-2, and the third light emitting element ED-3, respectively.

The display device DD of one or more embodiments may include a plurality of light emitting elements ED-1, ED-2, and ED-3, and at least any one of the light emitting elements ED-1, ED-2, or ED-3 may include emission layers EML-B, EML-G, and EML-R including quantum dots QD1, QD2, and QD3 according to one or more embodiments.

The display device DD according to one or more embodiments may include a display panel DP having a plurality of light emitting elements ED-1, ED-2, and ED-3 and an optical member PP disposed on the light control layer PP. In one or more embodiments, the light control layer PP may not be provided in the display device DD.

The display panel DP may include a base substrate BS, a circuit layer DP-CL and a display element layer DP-EL provided on the base substrate BS, and the display element layer DP-EL may include pixel defining films PDL, light emitting elements ED-1, ED-2 and ED-3 disposed between the pixel defining films PDL, and an encapsulation layer TFE disposed on the light emitting elements ED-1, ED-2 and ED-3.

The first emission layer EML-B of the first light emitting element ED-1 may include a first quantum dot QD1. The first quantum dot QD1 may be to emit blue light as a first light.

The second emission layer EML-G of the second light emitting element ED-2 and the third emission layer EML-R of the third light emitting element ED-3 may include a second quantum dot QD2 and a third quantum dot QD3, respectively. The second quantum dot QD2 and the third quantum dot QD3 may be to emit green light as a second light and red light as a third light, respectively.

At least one of the first to third quantum dots QD1, QD2, and/or QD3 may be a quantum dot according to one or more embodiments described above. In one or more embodiments, the second quantum dot QD2 may be a quantum dot according to one or more embodiments described above. However, the present disclosure is not limited thereto, and the first to third quantum dots QD1, QD2, and QD3 may each be a quantum dot according to one or more embodiments described above.

In one or more embodiments, the first to third quantum dots QD1, QD2, and QD3 included in the light emitting elements ED-1, ED-2, and ED-3 may be formed of different core materials. In one or more embodiments, the first to third quantum dots QD1, QD2, and QD3 may be formed of the same core material (or substantially the same core material), or two quantum dots selected from the first to third quantum dots QD1, QD2, and QD3 may be formed of the same core material (or substantially the same core material), and the rest may be formed of different core materials (or substantially different core materials).

In one or more embodiments, the first to third quantum dots QD1, QD2, and QD3 may have different diameters. For example, the first quantum dot QD1 utilized in the first light emitting element ED-1 emitting light in a relatively short wavelength range may have a relatively smaller average diameter than the second quantum dot QD2 of the second light emitting element ED-2 and the third quantum dot QD3 of the third light emitting element ED-3 each emitting light in a relatively long wavelength region.

In one or more embodiments, in the present description, the average diameter refers to the arithmetic mean of the diameters of a plurality of quantum dot particles. In one or more embodiments, the diameter of the quantum dot particle may be the average value of the width of the quantum dot particle in a cross section.

The relationship of the average diameters of the first to third quantum dots QD1, QD2, and QD3 is not limited to the above limitations. For example, FIG. 7 shows that the first to third quantum dots QD1, QD2, and QD3 are similar in size from one another, however, the first to third quantum dots QD1, QD2, and QD3 included in the light emitting elements ED-1, ED-2, and ED-3 may be different in size. In one or more embodiments, the average diameter of two quantum dots selected from the first to third quantum dots QD1, QD2, and QD3 may be similar, and the rest may be different.

In the display device DD of one or more embodiments, as shown in FIGS. 6 and 7, an area of each of the light emitting regions PXA-B, PXA-G, and PXA-R may be different in size from one another. In this case, the area may indicate an area when viewed on a plane defined by the first direction DR1 and the second direction DR2.

The light emitting regions PXA-B, PXA-G, and PXA-R may have different areas in size according to the color emitted from the emission layers EML-B, EL-G and EL-R of the light emitting elements ED-1, ED-2 and ED-3. For example, referring to FIGS. 6 and 7, the blue light emitting region PXA-B corresponding to the first light emitting element ED-1 emitting blue light may have a largest area, and the green light emitting region PXA-G corresponding to the second light emitting element ED-2 generating green light may have a smallest area in the display device DD of one or more embodiments. However, the present disclosure is not limited thereto, and the light emitting regions PXA-B, PXA-G, and PXA-R may be to emit light other than blue light, green light and red light, or the light emitting regions PXA-B, PXA-G, and PXA-R may have the same size or area (or substantially the same size or area), or the light emitting regions PXA-B, PXA-G, and PXA-R may be provided at different area ratios from those shown in FIG. 6.

The light emitting regions PXA-R, PXA-G, and PXA-B may each be a region separated by the pixel defining films PDL. The non-light emitting regions NPXA may be regions between neighboring light emitting regions PXA-B, PXA-G, and PXA-R, and may correspond to the pixel defining film PDL. In one or more embodiments, in the present description, each of the light emitting regions PXA-B, PXA-G, and PXA-R may correspond to a pixel. The pixel defining film PDL may separate the light emitting elements ED-1, ED-2 and ED-3. The emission layers EML-B, EML-G, and EML-R of the light emitting elements ED-1, ED-2 and ED-3 may be disposed and separated in openings OH defined by the pixel defining films PDL.

The pixel defining films PDL may be formed of a polymer resin. For example, the pixel defining films PDL may be formed including a polyacrylate-based resin or a polyimide-based resin. In one or more embodiments, the pixel defining films PDL may be formed by further including an inorganic material in addition to the polymer resin. In one or more embodiments, the pixel defining films PDL may be formed including a light absorbing material, or may be formed including a black pigment or a black dye. The pixel defining films PDL formed including a black pigment or a black dye may implement a black pixel defining film. When forming the pixel defining films PDL, carbon black may be utilized as a black pigment or a black dye, but the present disclosure is not limited thereto.

In one or more embodiments, the pixel defining films PDL may be formed of an inorganic material. For example, the pixel defining films PDL may be formed including silicon nitride (SiNx), silicon oxide (SiOx), silicon oxide (SiOxNy), and/or the like. The pixel defining film PDL may define light emitting regions PXA-B, PXA-G, and PXA-R. The light emitting regions PXA-B, PXA-G, and PXA-R, and a non-light emitting region NPXA may be separated by the pixel defining film PDL (e.g., the pixel defining film PDL may be included in the non-light emitting region NPXA, which separates the light emitting regions PXA-B, PXA-G, and PXA-R).

The light emitting elements ED-1, ED-2, and ED-3 may each include a first electrode EL1, a hole transport region HTR, one of emission layers EML-B, EML-G, or EML-R, an electron transport region ETR, and a second electrode EL2. In the light emitting elements ED-1, ED-2, and ED-3 included in the display device DD according to one or more embodiments, except that the quantum dots QD1, QD2, and QD3 included in the emission layers EML-B, EML-G, and EML-R are different from each other, the same description as indicated in FIG. 4 and/or the like may be equally applied to the first electrode EL1, the hole transport region HTR, the electron transport region ETR, and the second electrode EL2. In one or more embodiments, the light emitting elements ED-1, ED-2, and ED-3 may each further include a capping layer between the second electrode EL2 and the encapsulation layer TFE.

The encapsulation layer TFE may cover the light emitting elements ED-1, ED-2 and ED-3. The encapsulation layer TFE may be a single layer or a laminated layer of a plurality of layers. The encapsulation layer TFE may be a thin film encapsulation layer. The encapsulation layer TFE protects the light emitting elements ED-1, ED-2 and ED-3. The encapsulation layer TFE may cover an upper surface of the second electrode EL2 disposed in the opening OH, and may fill the opening OH.

In one or more embodiments, FIG. 7 and/or the like show that the hole transport region HTR and the electron transport region ETR are provided as a common layer while covering the pixel defining film PDL, but the present disclosure is not limited thereto. In one or more embodiments, the hole transport region HTR and the electron transport region ETR may be disposed in the opening OH defined in the pixel defining film PDL.

For example, when in addition to the emission layers EML-B, EML-G, and EML-R, the hole transport region HTR and the electron transport region ETR are provided through inkjet printing, the hole transport region HTR, the emission layer EML-B, EML-G, and EML-R, and the electron transport region ETR may be provided corresponding to the openings OH defined between the pixel defining films PDL. However, the present disclosure is not limited thereto, and, regardless of the method of providing each functional layer, as shown in FIG. 7, the hole transport region HTR and the electron transport region ETR may be provided as a common layer while covering the pixel defining films PDL without being patterned.

In the display device DD of one or more embodiments of FIG. 7, although the thicknesses of the emission layers EML-B, EML-G, and EML-R of the first to third light emitting elements ED-1, ED-2, and ED-3 are shown to be similar to one another, the present disclosure is not limited thereto. For example, in one or more embodiments, the thicknesses of the emission layers EML-B, EML-G, and EML-R of the first to third light emitting elements ED-1, ED-2, and ED-3 may be different from one another.

Referring to FIG. 7, the display device DD of one or more embodiments may further include a light control layer PP. The light control layer PP may block or reduce external light incident to the display panel DP from outside of the display device DD. The light control layer PP may block or reduce a part of the external light. The light control layer PP may perform a reflection preventing or reducing function minimizing or reducing reflection due to external light.

In one or more embodiments of FIG. 7, the light control layer PP may include a color filter layer CFL. For example, the display device DD of one or more embodiments may further include the color filter layer CFL disposed on the light emitting elements ED-1, ED-2, and ED-3 of the display panel DP.

In the display device DD of one or more embodiments, the light control layer PP may include a base layer BL and a color filter layer CFL.

The base layer BL may be a member providing a base surface on which the color filter layer CFL is disposed. The base layer BL may be a glass substrate, a metal substrate, a plastic substrate, and/or the like. However, the present disclosure is not limited thereto, and the base layer BL may be an inorganic layer, an organic layer, or a composite material layer.

The color filter layer CFL may include a light blocking unit BM and a color filter CF. The color filter may include a plurality of filters CF-B, CF-G, and CF-R. For example, the color filter layer CFL may include a first filter CF-B transmitting a first color light, a second filter CF-G transmitting a second color light, and a third filter CF-R transmitting a third color light. For example, the first filter CF-B may be a blue filter, the second filter CF-G may be a green filter, and the third filter CF-R may be a red filter.

Each of the filters CF-B, CF-G, and CF-R may include a polymer photosensitive resin and a pigment and/or a dye. The first filter CF-B may include a blue pigment and/or a blue dye, the second filter CF-G may include a green pigment and/or a green dye, and the third filter CF-R may include a red pigment and/or a red dye.

However, the present disclosure is not limited thereto, and the first filter CF-B may not include (e.g., may exclude) a (any) pigment or a (any) dye. The first filter CF-B may include a polymer photosensitive resin, but not include a pigment or a dye. The first filter CF-B may be transparent. The first filter CF-B may be formed of a transparent photosensitive resin.

The light blocking portion BM may be a black matrix. The light blocking unit BM may be formed including an organic light blocking material or an inorganic light blocking material, both (e.g., simultaneously) including a black pigment and/or a black dye. The light blocking unit BM may prevent or reduce light leakage, and separate boundaries between the adjacent filters CF-B, CF-G, and CF-R.

The color filter layer CFL may further include a buffer layer BFL. For example, the buffer layer BFL may be a protection layer protecting the filters CF-B, CF-G, and CF-R. The buffer layer BFL may be an inorganic material layer including at least one inorganic material among silicon nitride, silicon oxide, and/or silicon oxynitride. The buffer layer BFL may be formed of a single layer or a plurality of layers.

In one or more embodiments of FIG. 7, the first color filter CF-B of the color filter layer CFL is shown to overlap the second filter CF-G and the third filter CF-R, but the present disclosure is not limited thereto. For example, the first to third filters CF-B, CF-G and CF-R may be separated by the light blocking unit BM and may not overlap one another. In one or more embodiments, the first to third filters CF-B, CF-G and CF-R may be disposed correspondingly to the blue light emitting region PXA-B, green light emitting region PXA-G, and red light emitting region PXA-R, respectively.

Unlike what is shown in FIG. 7 and/or the like, the display device DD of one or more embodiments may include a polarizing layer as a light control layer PP instead of the color filter layer CFL. The polarizing layer may block or reduce external light provided to the display panel DP from the outside. The polarizing layer may block or reduce a part of external light.

In one or more embodiments, the polarizing layer may reduce reflected light generated in the display panel DP by external light. For example, the polarizing layer may function to block or reduce reflected light of a case where light provided from the outside the display device DD is incident to the display panel DP and exits again. The polarizing layer may be a circular polarizer having a reflection preventing or reducing function or the polarizing layer may include a linear polarizer and a λ/4 phase retarder. In one or more embodiments, the polarizing layer may be disposed on the base layer BL to be exposed or the polarizing layer may be disposed under the base layer BL.

Referring to FIG. 8, the display device DD-1 according to one or more embodiments may include a light conversion layer CCL disposed on the display panel DP-1. In one or more embodiments, the display device DD-1 may further include a color filter layer CFL. The color filter layer CFL may be disposed between the base layer BL and the light conversion layer CCL.

The display panel DP-1 may be a light emitting display panel. For example, the display panel DP-1 may be an organic electroluminescence display panel or a quantum dot light emitting display panel.

The display panel DP-1 may include a base substrate BS, a circuit layer DP-CL provided on the base substrate BS, and a display element layer DP-EL1.

In one or more embodiments, the light emitting element layer DP-EL1 may include a light emitting element ED-a, and the light emitting element ED-a may include a first electrode EL1 and a second electrode EL2 facing each other, and a plurality of functional layers FL disposed between the first electrode EL1 and the second electrode EL2. The plurality of layers OL may include a hole transport region HTR (see, e.g., FIG. 4), an emission layer EML (see, e.g., FIG. 4), and an electron transport region ETR (see, e.g., FIG. 4). An encapsulation layer TFE may be disposed on the light emitting element ED-a.

In the light emitting element ED-a, the same description as included with reference to FIG. 4 may be applied to the first electrode EL1, the hole transport region HTR, the electron transport region ETR, and the second electrode EL2. Yet, in the light emitting element ED-a included in the display panel DP-1 of one or more embodiments, the emission layer may include a host and a dopant, which are organic electroluminescence materials or may include the quantum dots according to one or more embodiments described above. In the display panel DP-1 of one or more embodiments, the light emitting element ED-a may be to emit blue light.

The light conversion layer CCL may include a plurality of barrier ribs BK disposed spaced apart from each other and light control units CCP-B, CCP-G, and CCP-R disposed between the barrier ribs BK. The barrier ribs BK may be formed including a polymer resin and a coloring additive. The barrier ribs BK may be formed including a light absorbing material, or formed including a pigment and/or a dye. For example, the barrier ribs BK may include a black pigment and/or a black dye to implement a black barrier rib. When forming the black barrier rib, carbon black and/or the like may be utilized as a black pigment or a black dye, but the present disclosure is not limited thereto.

The light conversion layer CCL may include a first light control unit CCP-B transmitting a first light, a second light control unit CCP-G including a fourth quantum dot QD2-a converting the first light into a second light, and a third light control unit CCP-R including a fifth quantum dot QD3-a converting the first light into a third light. The second light may be light of a longer wavelength range than the first light, and the third light may be light of a longer wavelength range than the first light and the second light. For example, the first light may be blue light, the second light may be green light, and the third light may be red light. The descriptions of the quantum dot according to one or more embodiments described above may be equally applied to at least one of the quantum dots QD2-a and QD3-a included in the light control units CCP-B, CCP-G, and CCP-R. For example, the descriptions of the quantum dot according to one or more embodiments described above may be equally applied to the fourth quantum dot QD2-a that converts the first light into the second light.

The light conversion layer CCL may further include a capping layer CPL. The capping layer CPL may be disposed above the light control units CCP-B, CCP-G, and CCP-R, and the barrier ribs BK. The capping layer CPL may serve to prevent or reduce penetration of moisture and/or oxygen (hereinafter, referred to as “moisture/oxygen”). The capping layer may be disposed on the light control units CCP-B, CCP-G, and CCP-R to prevent or reduce the light control units CCP-B, CCP-G, and CCP-R from being exposed to moisture/oxygen. The capping layer CPL may include at least one inorganic layer.

The display device DD-1 of one or more embodiments may include a color filter layer CFL disposed on the light conversion layer CCL, and the descriptions of FIG. 7 may be equally applied to the color filter layer CFL and the base layer BL of FIG. 8.

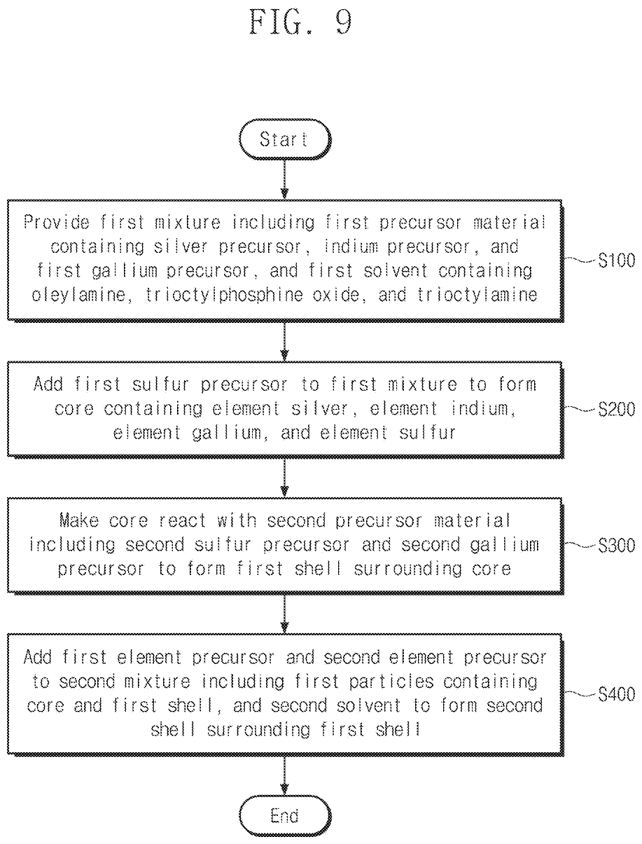

FIG. 9 is a flowchart showing a method for preparing a quantum dot according to one or more embodiments of the present disclosure.

Referring to FIG. 9, a method for preparing a quantum dot includes providing a first mixture including a first precursor material containing a silver precursor, an indium precursor, and a first gallium precursor, and a first solvent containing or including oleylamine, trioctylphosphine oxide, and trioctylamine (S100), adding a first sulfur precursor to the first mixture to form a core containing the element silver, the element indium, the element gallium, and the element sulfur (S200), making the core react with a second precursor material including a second sulfur precursor and a second gallium precursor to form a first shell around (e.g., surrounding) the core (S300), and adding a first element precursor and a second element precursor to a second mixture including first particles containing the core and the first shell, and a second solvent to form a second shell around (e.g., surrounding) the first shell (S400).

In the method for preparing a quantum dot according to one or more embodiments of the present disclosure, forming a core containing silver, indium, gallium, and sulfur may be performed first. As a starting material for forming the core, a first mixture including a first precursor material containing a silver precursor, an indium precursor, and a first gallium precursor, and a first solvent may be utilized.

The providing of the first mixture (S100) may include dispersing a first precursor material including a silver precursor, an indium precursor, and a first gallium precursor in a first solvent. The first solvent may be a material that coordinates a surface of the core to be prepared later and improves the dispersibility of the core. In one or more embodiments, the first solvent may affect light emission and electrical properties of the prepared quantum dots QD.

The first solvent may include oleylamine, trioctylphosphine oxide, and trioctylamine. The first solvent may serve to dissolve the first precursor material. The first solvent may serve to improve the dispersibility of the first precursor material in the first mixture. In a case where the first solvent includes oleylamine, when the first sulfur precursor is added to the first mixture in the forming of a core, which will be described later, reaction stability may be maintained even at a high temperature of 300° C. or higher.

In one or more embodiments, dissolving the first precursor material in an auxiliary solvent may be performed before the dispersing of the first precursor material in the first solvent, but the present disclosure is not limited thereto. When the first precursor material is dissolved in an auxiliary solvent in advance, the auxiliary solvent to be utilized may include at least one of hexane, toluene, chloroform, dimethyl sulfoxide, cyclohexylbenzene, hexadecane, or dimethyl formamide. However, the present disclosure is not limited thereto.

The silver precursor may be at least one of (e.g., one selected from the group consisting of) silver halide, silver acetate, and/or silver nitrate. For example, the silver precursor may be silver iodide (AgI). However, the present disclosure is not limited thereto.

The first gallium precursor may be at least one of (e.g., one selected from) gallium nitride, gallium phosphide, gallium(III) chloride, gallium(III) acetylacetonate, gallium(III) bromide, gallium(III) chloride, gallium(III) fluoride, gallium(III) iodide, gallium(III) nitrate hydrate, gallium(III) sulfate, and/or gallium(III) sulfate hydrate. For example, the first gallium precursor may be gallium iodide.

The indium precursor may be at least of (e.g., one selected from the group consisting of) indium(III) acetylacetonate, indium(III) chloride, indium(III) iodide, indium(III) acetate, trimethyl indium, alkyl indium, aryl indium, indium(III) myristate, indium(III) myristate acetate, and/or indium(III) myristate 2 acetate. For example, the indium precursor may be indium iodide.

The first mixture may include a silver precursor, an indium precursor, a first gallium precursor, oleylamine, trioctylphosphine oxide, and trioctylamine in a certain range. In one or more embodiments, the first mixture may include the silver precursor in an amount of about 0.1 mmol to about 1 mmol, the indium precursor in an amount of about 0.1 mmol to about 0.5 mmol, the first gallium precursor in an amount of about 0.3 mmol to about 1 mmol, the trioctylphosphine oxide in an amount of about 0.1 mmol to about 1 mmol, the oleylamine in an amount of about 10 mmol to about 50 mmol, and the trioctylamine in an amount of about 1 mmol to about 20 mmol.

For example, the first mixture may include silver iodide (AgI) in an amount of about 0.1 mmol to about 1 mmol as the silver precursor, Indium iodide (InI₃) in an amount of about 0.1 mmol to about 0.5 mmol as the indium precursor, gallium iodide (GaI₃) in an amount of about 0.3 mmol to about 1 mmol as the first gallium precursor, and a first solvent containing trioctylphosphine oxide in an amount of about 0.1 mmol to about 1 mmol, oleylamine in an amount of about 10 mmol to about 50 mmol, and trioctylamine in an amount of about 1 mmol to about 20 mmol. When the amounts of the first precursor material and the first solvent included in the first mixture satisfy the ranges described above, the uniformity of quantum dots QD formed thereafter increases and a stable facet is formed, resulting in high quantum yield and high color purity.

Thereafter, a first sulfur precursor may be added to the first mixture to form a core. The forming of the core may be heat-treating after the addition of the first sulfur precursor to the first mixture. The forming of the core may be making the silver precursor, the indium precursor, and the first gallium precursor included in the first mixture react with the first sulfur precursor. The silver precursor, the indium precursor, and the first gallium precursor included in the first mixture may react with the first sulfur precursor to form a core CO (see, e.g., FIG. 5).

In one or more embodiments, the first sulfur precursor may be added in an amount of about 1 mmol to about 2 mmol to the first mixture. When the amount of the first sulfur precursor added to the first mixture satisfies the range described above, the uniformity of the prepared quantum dots QD (see, e.g., FIG. 5) increases, and a stable facet is formed, resulting in high quantum yield and high color purity.

The first sulfur precursor may be at least one of (e.g., one selected from the group consisting of) trioctylphosphine-sulfide (TOP-S), tributylphosphine sulphide, triphenylphosphine sulfide, S-oleylamine (Sulfur-Oleylamine), element sulfur, octanethio, dodecanethiol, octadecanethiol, α-toluenethiol, allyl mercaptan, and/or bis(trimethylsilyl) sulfide. For example, the first sulfur precursor may be S-oleylamine.

In one or more embodiments, the adding of the first sulfur precursor to the first mixture may be performed in a first temperature condition. The first sulfur precursor may be added to the first mixture and then heat treated in a first temperature condition. However, the present disclosure is not limited to thereto, and the first mixture may be heated to a first temperature and then the first sulfur precursor may be added while the first temperature is kept. In one or more embodiments, the first temperature may be about 240° C. or higher. For example, the first temperature may be about 240° C. to about 350° C. In one or more embodiments, the first temperature may be about 300° C. to about 350° C. The heat-treating of the solution obtained through the adding of the first sulfur precursor to the first mixture at the first temperature may be performed at 300° C. As the adding of the first sulfur precursor to the first mixture is performed at 300° C. or higher, a stable facet may be formed in the reaction process, resulting in reduced trap emission of the finally formed quantum dots QD.

The method for preparing a quantum dot according to one or more embodiments may further include purifying the prepared core after the forming of the core. The purification may be performed utilizing chloroform, ethanol, acetone, or any combination thereof. However, the present disclosure is not limited thereto, and the purifying of the core in the method for preparing a quantum dot may not be provided depending on process conditions and/or the like.

After the forming of a core (S200), forming a first shell (S300) may be performed. The forming of the first shell may be adding a second precursor material including a second sulfur precursor and a second gallium precursor to a solution containing the core. After the adding of the second precursor material to a solution in which the purified core is dispersed in a solvent, the mixture may be subjected to a reaction at about 200° ° C. to about 250° C. Accordingly, the second sulfur precursor and the second gallium precursor may be subjected to a reaction to form a first shell around (e.g., surrounding) the core. In one or more embodiments, the core prepared herein and the first shell around (e.g., surrounding) the core may be collectively referred to as first particles.

The second sulfur precursor may be at least one of (e.g., one selected from the group consisting of) trioctylphosphine-sulfide (TOP-S), tributylphosphine sulphide, triphenylphosphine sulfide, S-oleylamine (sulfur-oleylamine), element sulfur, octanethio, dodecanethiol, octadecanethiol, α-toluenethiol, allyl mercaptan, and/or bis(trimethylsilyl) sulfide. For example, the second sulfur precursor may be S-oleylamine.

In one or more embodiments, the first sulfur precursor and the second sulfur precursor utilized in the method for preparing a quantum dot may be the same (or substantially the same). However, the present disclosure is not limited to thereto, and the first sulfur precursor utilized in the forming of the core and the second sulfur precursor utilized in the forming of the first shell may be different (or substantially different).

The second gallium precursor may be at least one of (e.g., one selected from) gallium nitride, gallium phosphide, gallium chloride, gallium acetylacetonate, gallium bromide, gallium chloride, gallium fluoride, gallium iodide, gallium nitrate hydrate, gallium sulfate, and/or gallium sulfate hydrate. For example, the second gallium precursor may be gallium chloride.

In one or more embodiments, the first gallium precursor and the second gallium precursor utilized in the method for preparing a quantum dot may be the same (or substantially the same). However, the present disclosure is not limited to thereto, and the first gallium precursor utilized in the forming of the core and the second gallium precursor utilized in the forming of the first shell may be different (or substantially different).

In one or more embodiments, the second precursor material may include the second sulfur precursor and the second gallium precursor in a certain range. The second precursor material may include the second sulfur precursor in an amount of about 1 mmol to about 2 mmol, and the second gallium precursor in an amount of about 1 mmol to about 5 mmol. When the amounts of the second sulfur precursor and the second gallium precursor reacting with the core prepared in the forming the core (S200) are within the above ranges, the uniformity of the quantum dots QD (see, e.g., FIG. 5) is improved, and a stable facet may be formed. Therefore, the quantum dots QD (see, e.g., FIG. 5) prepared through the method for preparing a quantum dot of one or more embodiments may exhibit improved quantum yield and high color reproducibility.

The method for preparing a quantum dot according to one or more embodiments may further include purifying the first particles including the core and the first shell around (e.g., surrounding) the core after the forming of the first shell. The purification may be performed utilizing chloroform, ethanol, acetone, or any combination thereof. However, the present disclosure is not limited thereto, and the purifying of the first particles in the method for preparing a quantum dot may not be provided depending on process conditions and/or the like.

After the forming of the first shell, adding a first element precursor and a second element precursor to a second mixture including first particles and a second solvent to form a second shell around (e.g., surrounding) the first shell may be performed.

The method for preparing a quantum dot according to one or more embodiments may further include preparing a preliminary second mixture before the forming of the second shell. The preliminary second mixture may include the first particles, the second solvent, and the third solvent. The preparing of the preliminary second mixture may include adding the second solvent to a solution in which the first particles are dissolved in the third solvent. The third solvent may be an auxiliary solvent added to improve the dispersibility of the first particles. The third solvent may be removed in the degassing of the preliminary second mixture, which will be described in more detail later.

In one or more embodiments, the third solvent may include hexane, toluene, chloroform, dimethyl sulfoxide, cyclohexylbenzene, hexadecane, or dimethyl formamide. However, the present disclosure is not limited thereto.

The method for preparing a quantum dot according to one or more embodiments may further include degassing the preliminary second mixture at a second temperature after the preparing of the preliminary second mixture. The degassing of the preliminary second mixture at a second temperature may form a second mixture including the first particles and the second solvent. The degassing of the preliminary second mixture at the second temperature may include degassing the preliminary second mixture including the first particles, the second solvent, and the third solvent at the second temperature. In one or more embodiments, the second temperature is not particularly limited, but may be about 110° C. or higher. For example, the second temperature may be about 110° C. to about 200° C.

In one or more embodiments, a boiling point of the third solvent included in the preliminary second mixture may be equal to or less than the second temperature. As the boiling point of the second mixture is lower than the second temperature, the third solvent may be evaporated in the degassing of the preliminary second mixture. The second mixture formed through the degassing of the preliminary second mixture may not include (e.g., may exclude) the third solvent. For example, the second mixture may include the first particles and the second solvent, but may not include (e.g., may exclude) the third solvent.

The first particle may indicate a core including silver, indium, gallium, and sulfur, and a first shell around (e.g., surrounding) the core. The first shell may include GaS. The first shell may be formed of GaS. However, the present disclosure is not limited thereto.

The second solvent may be a material that coordinates a surface of the quantum dots to be prepared later and improves the dispersibility of the quantum dots. In one or more embodiments, the second solvent may affect light emission and electrical properties of the prepared quantum dots.

The second solvent may include oleylamine, octylamine, decylamine, trioctylamine, hexadecylamine, mercaptopropionicacid, dodecanethiol, 1-octanethiol, thionylchloride, trioctylphosphine, trioctylphosphine oxide, hexylphosphonic acid, tetradecylphosphonic acid, octylphosphonic acid, or any combination thereof. In one or more embodiments, the second solvent may include at least one of oleylamine or trioctylamine.

The second mixture may include the first particles and the second solvent in a certain range. In one or more embodiments, the second mixture may include the first particles in an amount of about 0.1 mmol to about 100 mmol, and the second solvent in an amount of about 10 mmol to about 100 mmol. When the amounts of the first particles and the second solvent included in the second mixture are regulated within the above ranges, the quantum dots QD has an increased blue light absorption rate, and may thus have high quantum yield.

In one or more embodiments, the adding of the first element precursor and the second element precursor to the second mixture may be performed in an inert gas atmosphere. The inert gas may include a noble gas having low reactivity and also nitrogen having relatively lower reactivity than other gases.

The amounts of the first element precursor and the second element precursor added to the second mixture may be regulated within a certain range. In one or more embodiments, the first element precursor may be added in an amount of about 1 mmol to about 10 mmol, and the second element precursor may be added in an amount of about 1 mmol to about 10 mmol. As the amounts of the first element precursor and the second element precursor added to the second mixture satisfy the range described above, the prepared quantum dots QD (see, e.g., FIG. 5) may have an increased absorption rate, and may thus have high quantum yield.

The first element precursor and the second element precursor may each independently include at least one of a Group II element, a Group III element, a Group V element, a Group VI element, or a VII element. For example, the first element precursor and the second element precursor may each independently be a compound including at least one of a Group II element, a Group III element, a Group V element, a Group VI element, or a VII element. For example, the first element precursor and the second element precursor may each independently include at least one of a Group II precursor, a Group III precursor, a Group V precursor, a Group VI precursor, or a Group VII precursor.

In one or more embodiments, the first element precursor may be a compound including at least one of a Group II element, a Group III element, or a VII element, and the second element precursor may be a compound including at least one of a Group II element, a Group V element, or a Group VI element. For example, the first element precursor may include at least one of a Group II element precursor, a Group III element precursor, or a VII element precursor. The second element precursor may include at least one of a Group II element precursor, a Group V element precursor, or a Group VI element precursor. In one or more embodiments, the first element precursor may be a Group II element precursor, and the second element may be a Group V element precursor.

The Group II precursors may include a zinc precursor. The zinc precursor may be at least one of (e.g., one selected from the group consisting of), for example, dimethyl zinc, diethyl zinc, zinc acetate, zinc acetylacetonate, zinc stearate, zinc iodide, zinc bromide, zinc chloride, zinc fluoride, zinc carbonate, zinc cyanide, zinc nitrate, zinc oxide, zinc peroxide, zinc perchlorate, and/or zinc sulfate. However, the present disclosure is not limited thereto.

The Group III precursor may be at least one of (e.g., one selected from the group consisting of) aluminum phosphate, aluminum acetylacetonate, aluminum chloride, aluminum fluoride, aluminum oxide, aluminum nitrate, aluminum sulfate, allium acetylacetonate, gallium chloride, gallium fluoride, gallium oxide, gallium nitrate, and/or gallium sulfate. However, the present disclosure is not limited thereto.

The Group V precursor may be at least one of (e.g., one selected from the group consisting of) alkyl phosphine, tris(trialkylsilyl)phosphine, tris(dialkylsilyl)phosphine, tris(dialkylamino phosphine), arsenic oxide, arsenic chloride, arsenic sulfate, arsenic bromide, and/or arsenic iodide. However, the present disclosure is not limited thereto. In this case, the alkyl phosphine may be at least any one of triethyl phosphine, tributyl phosphine, trioctyl phosphine, triphenyl phosphine, or tricyclohexyl phosphine.

The Group VI precursor may be at least one of (e.g., one selected from the group consisting of) sulfur, trialkylphosphine sulfide, trialkenylphosphine sulfide, alkylamino sulfide, alkenylamino sulfide, and alkyl thiol, selenium, trialkylphosphine selenide, trialkenylphosphine selenide, alkylamino selenide, alkenylamino selenide, trialkylphosphine telluride, trialkenylphosphine telluride, alkylamino telluride, and/or alkenylamino telluride. However, the present disclosure is not limited thereto.

Group VII precursor is at least one of (e.g., one selected from the group consisting of) manganese oxide, manganese carbonate, manganese nitrate hydrate, manganese sulfate, and/or manganese chloride. However, the present disclosure is not limited thereto.

When the second shell SH2 has a multilayer structure, the forming of the second shell (S400) may be continuously performed two times or more. In this case, any one of the type or kind, amount, and reaction temperature conditions of the first element precursor may be different, but the present disclosure is not limited thereto.

The method for preparing quantum dots QD according to one or more embodiments may further include ashing the prepared quantum dots QD after the forming of the second shell. The ashing of the quantum dots QD may be performing a reaction at about 200° C. after adding trioctylphosphine. However, the present disclosure is not limited thereto. Thereafter, the mixture in which the quantum dot is formed is cooled to room temperature, purified, and redispersed to prepare quantum dots having high purity. The purification and redispersion may further include adding a nonsolvent to the mixture in which the quantum dots are formed to separate the quantum dots. The non-solvent may be a polar solvent that is miscible with an organic solvent utilized in the reaction but not capable of dispersing the quantum dots.

The non-solvent may be determined depending on the organic solvent utilized in the reaction, and may be at least one of (e.g., one selected from the group consisting of) acetone, ethanol, butanol, isopropanol, ethanediol, water, tetrahydrofuran, dimethylsulfoxide, diethyl ether, formaldehyde, acetaldehyde, and/or ethylene glycol. However, the present disclosure is not limited thereto.

In one or more embodiments, centrifugation, precipitation, chromatography, or distillation may be utilized to separate the quantum dots. The separated quantum dots may be added to a washing solvent as needed and then washed. The solvent for washing is not particularly limited, and hexane, heptane, octane, chloroform, toluene, benzene and/or the like may be utilized.

Hereinafter, with reference to Examples and Comparative Examples, quantum dots according to one or more embodiments of the present disclosure will be specifically described. In one or more embodiments, Examples are shown only to aid in the understanding of the present disclosure, and the scope of the present disclosure is not limited thereto.

### Examples

### Synthesis of Example 1

### Step 1: Synthesis of AgInGaS Core

0.4 mmol of AgI, 0.57 mmol of GaI₃, and 0.33 mmol of InI₃ were mixed with 15.19 mmol of oleylamine, 0.85 mmol of trioctylphosphine oxide (TOPO), and 11.45 mmol of trioctylamine (TOA) in a three-neck flask, and then the mixture was degassed and stirred at 120° ° C. for 60 minutes to remove oxygen and moisture inside, thereby forming a reaction solution. Thereafter, 1.6 mmol of sulfur-oleylamine was added to the reaction solution in an argon atmosphere, and the mixture was heated to 240° C., kept for a certain period of time, and then cooled to 200° C., and 4.48 mmol of TOP was injected thereto, and the mixture was subjected to a reaction for a certain period of time to synthesize a core.

### Step 2: Synthesis of AgInGaS/GaS

0.5 mmol of the synthesized AgInGaS core was diluted in toluene, precipitated with ethanol, and purified, and then, the AgInGaS Core, 1.6 mmol of sulfur-oleylamine, and 2.27 mmol of GaCl₃ were added to oleylamine degassed at 120 ºC to form a GaS shell at 200° C. or higher.

### Step 3: Synthesis of AgInGaS/GaS/ZnS

The synthesized AgInGaS/GaS quantum dots were diluted in toluene and precipitated with ethanol, and purified. Then, after dispersing 0.5 mmol of purified AgInGaS/GaS quantum dots in toluene, 24.3 mmol of oleylamine was mixed and degassed at 120° C. Thereafter, 1.6 mmol of sulfur-oleylamine, 2.27 mmol of trioctylphosphine-sulfide, and 0.3 mmol of ZnCl₂ were added to form a ZnS shell at 200° C. or higher.

### Synthesis of Example 2

Compared to Example 1, quantum dots were prepared in substantially the same manner as in Example 1, except that the reaction temperature was set to 300° C. in the adding of the first sulfur precursor to the first mixture.

### Synthesis of Comparative Example 1

In Comparative Example 1, quantum dots were prepared in substantially the same manner as in Example 1, except that a second shell was not formed compared to Example 1.

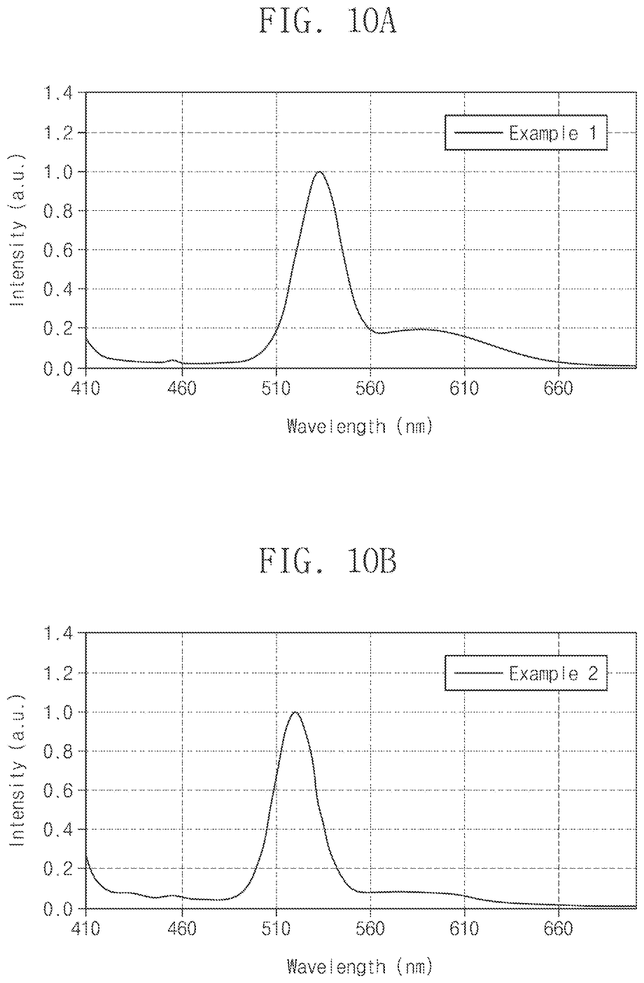

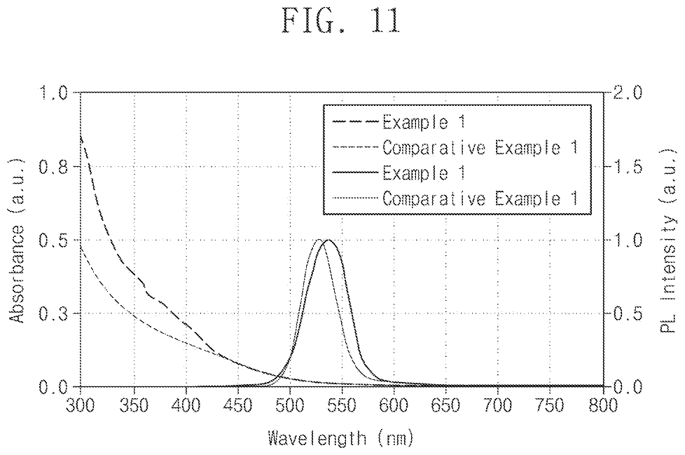

FIG. 10A is a graph showing a photoluminescence (PL) spectrum of a quantum dot of Example 1. FIG. 10B is a graph showing a photoluminescence spectrum of a quantum dot of Example 2. In the graphs shown in FIGS. 10A and 10B, the vertical axis represents emission intensity, and the horizontal axis represents the emission wavelength range.

Referring to FIGS. 10A and 10B, it is seen that the quantum dots of Examples have a first emission peak showing high emission intensity in a wavelength of about 510 mm to about 540 nm. The first emission peak may be generated through band-edge emission. It is seen that the quantum dots formed through the method for preparing a quantum dot of one or more embodiments exhibit high emission intensity in a wavelength of about 510 mm to about 540 nm. Therefore, the method for preparing a quantum dot according to one or more embodiments may provide a quantum dot having excellent or suitable light emitting properties due to the high emission intensity.

In one or more embodiments, referring to FIG. 10A, it is seen that the quantum dots formed through the method for preparing a quantum dot of Example 1 exhibit a second emission peak of about 560 nm to about 630 nm in addition to the first emission peak of about 510 nm to about 540 nm. The first emission peak of Example 1 may indicate a peak generated through bend-edge emission, and the second emission peak may indicate a peak generated through trap emission. In one or more embodiments, in the present specification, the bend-edge emission may indicate emission generated due to a transition from a conduction band to a valence band of quantum dots. The trap emission may indicate emission generated due to defects in gaps of quantum dots. The intensity of trap emission may be proportional to the number of defect sites formed in quantum dots. Therefore, it is seen that the quantum dots of Example 1 have an increased trap emission intensity compared to Example 2 due to an increased number of defect sites.

Referring to FIG. 10B, it is seen that the intensity of the second emission peak corresponding to trap emission is reduced in the quantum dots of Example 2 compared to the quantum dots of Example 1. When the process temperature is regulated to 300° C. or higher in the adding of the first sulfur precursor to the first mixture as in Example 1, a stable facet may be formed upon reactions. Therefore, in the quantum dots of Example 2, compared to the quantum dots of Example 1, the trap emission may be effectively suppressed or reduced, and thus, color purity may be further improved.

FIG. 11 shows absorption and emission spectra of Example 1 and Comparative Example 1. The quantum dots of Example 1 include a core containing silver, indium, gallium, and sulfur, a first shell around (e.g., surrounding) the core and containing GaS, and a second shell. For example, the quantum dots of Example 1 are quantum dots having an AgInGaS/GaS/ZnS structure. The quantum dots of Comparative Example 1 have the same structure as the quantum dots of Example 1, except that a second shell is not included. For example, Comparative Example 1 is quantum dots having an AgInGaS/GaS structure. The quantum dots of Comparative Example 1 may be first particles in a state prior to forming a second shell in the method for preparing a quantum dot according to one or more embodiments.

Referring to FIG. 11, it is seen that the quantum dots of Example 1 and Comparative Example 1 each have an emission wavelength of about 510 nm to about 540 nm. In one or more embodiments, it is seen that the quantum dots of Example 1 and Comparative Example 1 exhibit absorption wavelengths in the wavelength of about 300 nm to about 500 nm. However, it is seen that the absorption spectrum of Example 1 exhibits high absorbance in the wavelength of about 300 nm to about 430 nm compared to Comparative Example 1. Therefore, the quantum dots according to one or more embodiments include the second shell around (e.g., surrounding) the first shell, and as the amounts of the first element precursor and the second element precursor added in the preparation process are regulated to a certain range, quantum dots having a high blue light absorption rate may be provided. Accordingly, when the quantum dots prepared through the method for preparing a quantum dot of one or more embodiments are applied to a display device, excellent or suitable color reproducibility may be obtained.

Table 1 shows the evaluation of light emitting properties, quantum yields, and quantum yield retentions of the quantum dots according to Example 2 and Comparative Example 1. In Table 1, the emission wavelength, full width of half maximum (FWHM), quantum yield (QY), and quantum yield retention of the quantum dots of each Example 2 and Comparative Example 1 were determined. Table 1 shows the quantum yield retention calculated through Equation 1 above.

TABLE 1

| | | Full width at | Quantum | Quantum yield |
|---|---|---|---|---|
| | PL(nm) | half maximum(nm) | yield (%) | retention (%) |
| Example 2 | 529 | 33 | 83 | 91 |
| Comparative | 540 | 35 | 73 | 73 |
| Example 1 | | | | |

Referring to Table 1, it is seen that the quantum dots of Example 2 have a narrower full width of half maximum and higher quantum yield than the quantum dots of Comparative Example 1. Even in the quantum yield retention, it is seen that the quantum dots of Example 2 exhibit greater retention than Comparative Example 1. The quantum dots of one or more embodiments exhibit high quantum yield retention of 90% or greater and have high stability, and may thus provide improved light emitting properties. Therefore, the quantum dots of Example 2 may exhibit higher light emitting efficiency and higher color purity than the quantum dots of Comparative Example 1.

AgInGaS quantum dots, which are I-III-VI semiconductor compounds, may exhibit defect emission due to recombination of charges at defect levels within the band gap. In particular, I-III-VI quaternary semiconductor compounds such as AgInGaS quantum dots have various defects described above due to the increased degree of freedom, which is caused by the inclusion of three cations. For this reason, a method for reducing defect emission by introducing a GaS shell around (e.g., surrounding) the AgInGaS core may be utilized, but the quantum dots containing an AgInGaS/GaS core/shell structure have low chemical stability due to the amorphous shape of the GaS shell. Therefore, even when the GaS shell is applied to the AgInGaS core, there is a limit to completely prevent or reduce trap emissions.

According to one or more embodiments of the present disclosure, the quantum dots of one or more embodiments include a core containing Ag, In, Ga, and S, a first shell around (e.g., surrounding) the core and containing GaS, and a second shell around (e.g., surrounding) the first shell, and may thus maintain high band-edge emission and also exhibit high quantum yield and high quantum yield retention. In one or more embodiments, the method for preparing a quantum dot according to one or more embodiments of the present disclosure regulates a precursor composition and reaction temperature and may thus ensure the chemical stability of quantum dots, and a stable facet may be formed in the reaction process to reduce trap emission. Therefore, when the quantum dots prepared through the method for preparing a quantum dot of one or more embodiments are applied to a light emitting element, excellent or suitable light efficiency and reliability may be obtained.

According to a display panel of one or more embodiments of the present disclosure, a barrier rib included in a light control layer includes a first sub-barrier rib and a second sub-barrier rib, which have different transmittances, and accordingly, the light control layer may have improved light conversion efficiency, film durability, and chemical resistance. Accordingly, the display panel including the light control layer may have improved display efficiency and reliability. As used herein, the term “substantially,” “about,” and similar terms are used

as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure has been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A method for preparing a quantum dot, the method comprising:
supplying a first mixture comprising
a first precursor material comprising a silver precursor, an indium precursor, and a first gallium precursor, and
a first solvent comprising oleylamine, trioctylphosphine oxide, and trioctylamine;
adding a first sulfur precursor to the first mixture to form cores, each of the cores comprising silver, indium, gallium, and sulfur;
reacting the cores with a second precursor material comprising a second sulfur precursor and a second gallium precursor to form a first shell around each of the cores, wherein the cores comprising the first shells comprise first particles; and
adding a first element precursor and a second element precursor to a second mixture, the second mixture comprising the first particles and a second solvent, to form a second shell around each of the first shells,
wherein the first element precursor and the second element precursor each independently include at least one of a Group II element, a Group III element, a Group V element, a Group VI element, or a VII element.

2. The method of claim 1, wherein the first mixture comprises:
the silver precursor in an amount of about 0.1 mmol to about 1 mmol;
the indium precursor in an amount of about 0.1 mmol to about 0.5 mmol;
the first gallium precursor in an amount of about 0.3 mmol to about 1 mmol;
the trioctylphosphine oxide in an amount of about 0.1 mmol to about 1 mmol;
the oleylamine in an amount of about 10 mmol to about 50 mmol; and
the trioctylamine in an amount of about 1 mmol to about 20 mmol.

3. The method of claim 1, wherein the second precursor material comprises:
the second sulfur precursor in an amount of about 1 mmol to about 2 mmol; and
the second gallium precursor in an amount of about 1 mmol to about 5 mmol.

4. The method of claim 1, wherein the second mixture comprises:
the first particles in an amount of about 0.1 mmol to about 100 mmol; and
the second solvent in an amount of about 10 mmol to about 100 mmol.

5. The method of claim 1, wherein the second solvent comprises at least one of oleylamine or trioctylamine.

6. The method of claim 1, wherein, in the forming of the second shell,
the first element precursor is added in an amount of about 1 mmol to about 10 mmol, and
the second element precursor is added in an amount of about 1 mmol to about 10 mmol.

7. The method of claim 1, wherein the adding of the first sulfur precursor to the first mixture is performed in a first temperature, and
the first temperature is 300° C. or greater.

8. The method of claim 1, further comprising degassing the second mixture at a second temperature before the forming of the second shell.

9. The method of claim 8, wherein the second mixture further comprises a third solvent, and a boiling point of the third solvent is equal to or less than the second temperature.

10. A quantum dot comprising:
a core comprising silver, indium, gallium, and sulfur;
a first shell around the core and comprising GaS; and
a second shell around the first shell and comprising a first element, wherein the first element comprises at least one of a Group II element, a Group III element, a Group V element, a Group VI element, or a Group VII element.

11. The quantum dot of claim 10, wherein the second shell comprises at least any one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

12. The quantum dot of claim 10, wherein the first shell has a thickness of about 0.5 nm to about 3 nm, and the second shell has a thickness of about 0.5 nm to about 4 nm.

13. The quantum dot of claim 10, wherein the second shell is thicker than the first shell.

14. The quantum dot of claim 10, wherein the core has a diameter of about 3 nm to about 7 nm.

15. The quantum dot of claim 10, wherein the core comprises the silver in an amount of about 10 at % to about 20 at %, the indium in an amount of about 5 at % to about 30 at %, the gallium in an amount of about 0.2 at % to about 15 at %, and the sulfur in an amount of about 50 at % to about 60 at %.

16. The quantum dot of claim 10, wherein a ratio of the number of atoms of gallium in the entire quantum dot to the number of atoms of indium in the entire quantum dot is about 0.01 to about 2, and
a ratio of the number of atoms of the first element in the entire quantum dot to the number of atoms of indium in the entire quantum dot is about 0.5 to about 1.

17. The quantum dot of claim 10, wherein the quantum dot has a central emission wavelength of about 510 nm to about 540 nm.

18. The quantum dot of claim 10, wherein a quantum yield retention represented by Equation 1, of the quantum dot, is about 90% or greater:
quantum yield retention=X₁/X₀, and Equation 1
wherein in Equation 1,
X₁ is a quantum yield of the quantum dot as measured after three times of purification with ethanol, and
X₀ is a quantum yield of the quantum dot before the purification.

19. A light emitting element comprising:
a first electrode;
a hole transport region on the first electrode;
an emission layer on the hole transport region and comprising quantum dots;
an electron transport region on the emission layer; and
a second electrode on the electron transport region,
wherein each of the quantum dots include a core comprising silver, indium, gallium, and sulfur, a first shell around the core and comprising GaS, and a second shell around the first shell and comprising a first element, and
wherein the first element comprises at least one of a Group II element, a Group III element, a Group V element, a Group VI element, or a Group VII element.

20. The light emitting element of claim 19, wherein the second shell comprises at least any one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.
